(19) United States
(12) Patent Application Publication
(10) Pub. No.: US 2006/0219283 A1
(43) Pub. Date: Oct. 5, 2006

(54) Temperature variation power generator

(76) Inventor: I-Min Chang, Taipei City (TW)

Correspondence Address: RABIN & BERDO, P.C., Suite 500, 1101 14 Street, N.W., Washington, DC, 20005, US

(21) Appl. No.: 11/092,694

(22) Filed: Mar. 30, 2005

(51) Int. Cl. H01L 35/30

(52) U.S. Cl. 136/205

(57) ABSTRACT

A temperature variation power generator comprising a plurality of N type and P type semiconductor elements to form an electronic component with two extension wires on the front and end, the N type and P type semiconductor elements are aligned in array and fixed by two heat-conductive boards on top and bottom. Based on the structure described above, while application, users can heat or freeze on the surface of one of the boards, the heat absorbed by the board is transmitted to the bottom of the N type and P type semiconductor elements, the temperature variation between top and bottom of the N type, P type semiconductor elements generates weak electrical current, the electronic component accumulates all the weak current in series to form a electrical power with proper voltage and current available to be applied on small DC motors or small 3C electronic devices.

### BACKGROUND OF THE INVENTION

I. Field of the Invention

This invention relates generally to a power generator and, more specifically, to a temperature variation power generator that is noiseless while application to achieve environment protection effect.

II. Description of the Prior Art

Heretofore, it is known the structure of the power generators, especially a small type of power generators apply gasoline or diesel as fuel, even though these kind of power generators can offer higher current and voltage, however the physical size is bulky, the weight is very heavy and not so easy to carry around, the noise is loud and easy to cause air pollution for incomplete burning; such might not easy for personal application, especially not easy for 3C electronic devices.

### SUMMARY OF THE INVENTION

It is therefore a primary object of the invention to provide a temperature variation power generator that applies temperature variation to generate effective electrical current for small DC motors or different 3C electronic devices.

It is still an object for the invention to provide a temperature variation power generator in which the compact physical size and light weight characters make it easy to carry or be applied inside electrical devices.

It is still another object for the invention to provide a temperature variation power generator in which is noiseless while application to be environment protection.

In order to achieve the objective set forth, a temperature variation power generator in accordance with the present invention comprises a plurality of N type and P type semiconductor elements to form an electronic component with two extension wires on the front and end, the N type and P type semiconductor elements are aligned in array and fixed by two heat-conductive boards (Aluminum, copper or ceramic boards) on top and bottom.

Based on the structure described above, while application, users can heat or freeze on the surface of one of the boards, the heat absorbed by the board is transmitted to the bottom of the N type and P type semiconductor elements, the temperature variation between top and bottom of the N type, P type semiconductor elements generates weak electrical current, the electronic component accumulates all the weak current in series to form a electrical power with proper voltage and current available to be applied; for example, a semiconductor element with 30×30×4.0 mm in physical size is heated with a candle light, a current in 200 mA with 2V electrical power is generated between two extension wires, such power can drive a small DC motor or small electronic devices; the heat source of the present invention can be small gas lamps, ice cube or cigarette lighters that is easy to access; the present invention applies temperature variation that will not introduce noise for better environment protection.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is an assembly view of the present invention;

FIG. 2 is a cross-sectional view of the present invention;

FIG. 3 is the first application view of the present invention;

FIG. 4 is the second application view of the present invention;

FIG. 5 is another application view of the present invention.

### DESCRIPTION OF THE PREFERRED EMBODIMENT

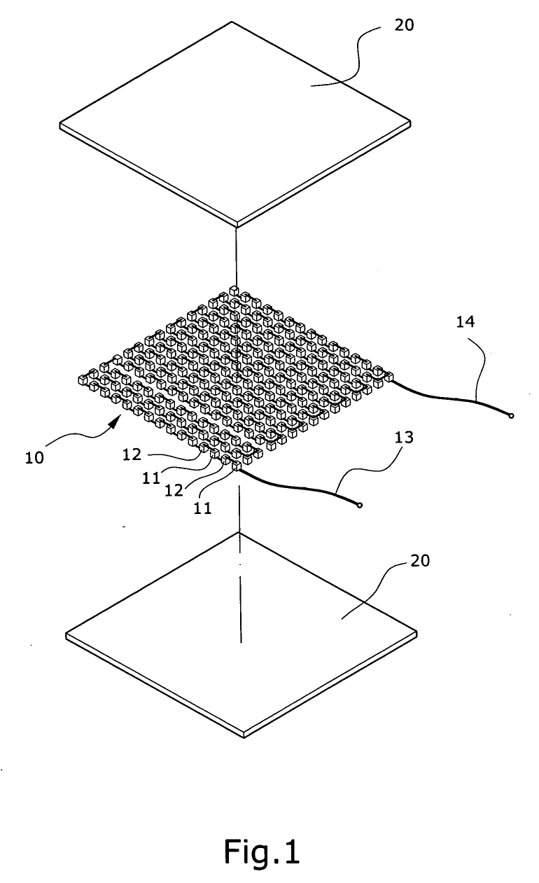

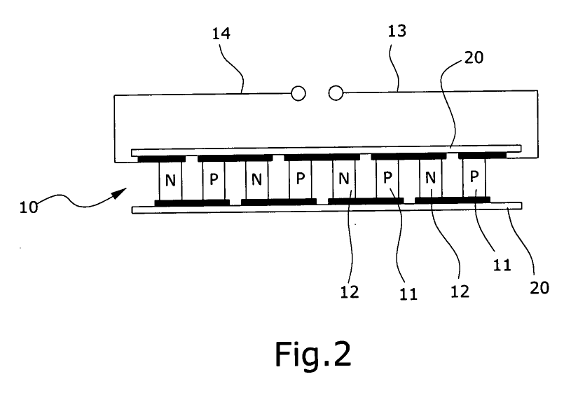

Referring to FIG. 1 and FIG. 2, the present invention comprises a plurality of N type and P type semiconductor elements 11, 12 to form an electronic component 10 with two extension wires 13, 14 on the front and end, the N type and P type semiconductor elements 11, 12 are aligned in array and fixed by two heat-conductive boards 20 (Aluminum, copper or ceramic boards) on top and bottom.

Based on the structure described above, while application, users can heat or freeze on the surface of-one of the boards 20, the heat absorbed by the board 20 is transmitted to the bottom of the N type and P type semiconductor elements 11, 12, the temperature variation between top and bottom of the N type, P type semiconductor elements 11, 12 generates weak electrical current, the electronic component 10 accumulates all the weak current in series to form a electrical power with proper voltage and current available to be applied; for example, a semiconductor element with 30×30×4.0 mm in physical size is heated with a candle light, a current in 200 mA with 2V electrical power is generated between two extension wires 13, 14, such power can drive a small DC motor or small electronic devices; the heat source of the present invention can be small gas lamps, ice cube or cigarette lighters that is easy to access; the present invention applies temperature variation that will not introduce noise for better environment protection.

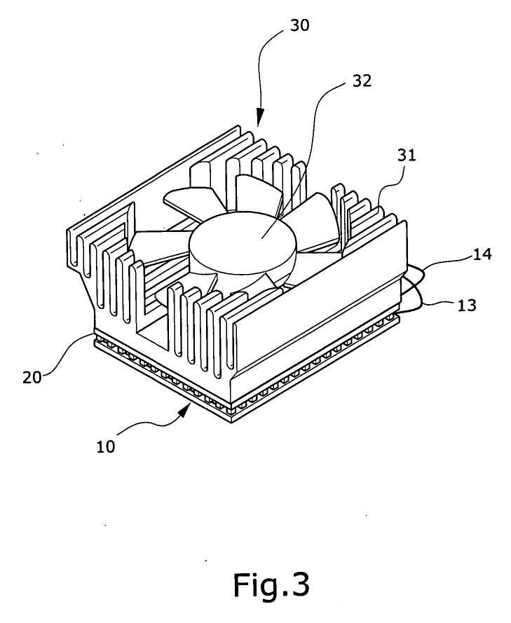

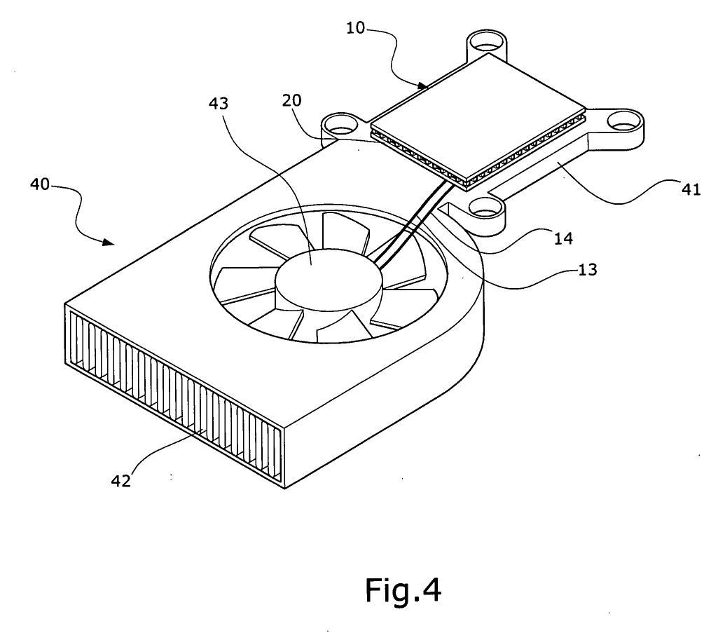

Referring to FIG. 3 and FIG. 4, the first application example on PC, a CPU heat sink 30 is stuck firmly on top board 20 of the electronic component 10; the heat sink 30 consists of at least one heat-sinking fin 31 and a fan 32, the extension wires 13, 14 of the electronic component 10 are connected to the fan 32 of the heat sink 30, the generated electrical power can be applied to the PC; the second application example on laptop computer, the bottom board 20 of the electronic component 10 is stuck firmly on top of the CPU heat sink 40; the heat sink 40 consists of a heat dissipation board 41, heat-sinking fins 42 and a fan 43, the extension wires 13, 14 of the electronic component 10 are connected to the positive and negative connectors of the fan 43 of the heat sink 30, the generated electrical power can be applied to the laptop computers.

While application, the bottom board 20 of the electronic component 10 sticks firmly to the top of the CPU; the heat generated by CPU is absorbed by the bottom board 20 initially, at the same time, the electronic component 10 generates DC current to drive the fan 32 (43) turning, that can further achieve better heat dissipation effect without the internal power of PC's to save wiring, also achieve long usage period of laptop computers.

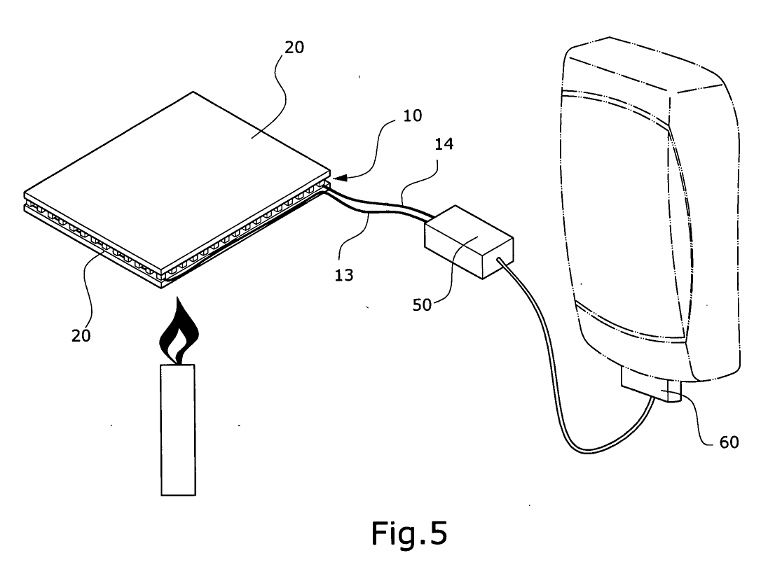

Referring to FIG. 5, another application example, the extension wires 13, 14 of the electronic component 10 are connected to a regulation power circuitry 50, the output of the regulation power circuitry 50 connects to an USB (Universal Serial Bus) connector 60 as a temporary power supply; while outdoors and mobile phone or PDA is out of power, users can heat up the bottom board 20 of the electronic component 10 and connect the USB connector to the mobile phone to charge and contact others.

While a preferred embodiment of the invention has been shown and described in detail, it will be readily understood and appreciated that numerous omissions, changes and additions may be made without departing from the spirit and scope of the invention.

What is claimed is:

1. A temperature variation power generator comprising:
a plurality of N type and P type semiconductor elements to form an electronic component with two extension wires on the front and end, the N type and P type semiconductor elements are aligned in array and fixed by two heat-conductive boards on top and bottom.

2. The temperature variation power generator recited in claim 1, wherein said extension wires of said electronic component connect to positive and negative connectors of the fan of a CPU heat sink to form a CPU heat sink without power supply.

3. The temperature variation power generator recited in claim 2, wherein said electronic component is stuck on bottom of the heat sink.

4. The temperature variation power generator recited in claim 2, wherein said electronic component is stuck on top of the heat sink.

5. The temperature variation power generator recited in claim 1, wherein said extension wires of said electronic component are connected to a regulation power circuitry, the output of said regulation power circuitry connects to a connector as a temporary power supply.
